(19) United States
(12) Patent Application Publication
(10) Pub. No.: US 2012/0040516 A1
(43) Pub. Date: Feb. 16, 2012

(54) METHOD AND DEVICE FOR DEPOSITING SEMICONDUCTOR FILM ON SUBSTRATE USING CLOSE-SPACED SUBLIMATION PROCESS

(76) Inventor: Shenjiang XIA, Hangzhou (CN)

(21) Appl. No.: 13/276,340

(22) Filed: Oct. 19, 2011

Related U.S. Application Data
(63) Continuation of application No. PCT/CN2009/073089, filed on Aug. 5, 2009.

(30) Foreign Application Priority Data
Apr. 23, 2009 (CN) 200910097899.2

(51) Int. Cl. H01L 21/20; C23C 14/24

(52) U.S. Cl. 438/478; 118/726; 118/724; 257/E21.09

(57) ABSTRACT

A method and device for depositing a semiconductor film. The method includes: a) carrying a semiconductor material by a carrier gas to a crucible installed in a vacuum deposition chamber via a passage; and b) heating the crucible to sublimate the semiconductor material to be vapor and depositing the vapor on a substrate. The device includes a semiconductor material feeding device, a passage, a vacuum deposition chamber, a crucible installed in the vacuum deposition chamber, and a substrate located above the crucible. The semiconductor material feeding device and the crucible are connected via the passage. The semiconductor material feeding device supplies semiconductor material and carrier gas. The semiconductor material is carried by the carrier gas and enters the crucible via the passage. The method and device can supply semiconductor materials continuously or periodically without opening a vacuum deposition chamber thereof and the uniformity of thin film can be controlled effectively.

### CROSS-REFERENCE TO RELATED APPLICATIONS

This application is a continuation of International Patent Application No. PCT/CN2009/073089, with an international filing date of Aug. 5, 2009, designating the United States, now pending, and further claims priority benefits to Chinese Patent Application No. 200910097899.2, filed Apr. 23, 2009. The contents of all of the aforementioned applications, including any intervening amendments thereto, are incorporated herein by reference.

### BACKGROUND OF THE INVENTION

1. Field of the Invention

The invention relates to a semiconductor film deposition technique, and more particularly to a method and device for depositing a semiconductor material to form a thin film on substrates using close-spaced sublimation techniques.

2. Description of the Related Art

In the manufacturing of the CdS/CdTe solar cell, a process called close-spaced sublimation which can produce high quality CdTe film is attracting attention recently. The process can produce a CdS/CdTe solar cell with the highest conversion coefficient (16.8%) in the world. The close-spaced sublimation process is a kind of vapor deposition process. Materials for forming the CdTe film (hereinafter referred to as a source) are placed in a crucible made of graphite. A glass sheet substrate on which CdTe film is deposited in the close-spaced sublimation process is located on the top of the crucible. A thermal insulating spacer is used to separate the glass sheet substrate and thermal conductive crucible. The distance between the glass sheet substrate and the top surface of the source is about between 0.5 and 5 cm. In this manner, the source sublimates and then deposits on the glass sheet substrate to form a semiconductor layer. In general, in the close-spaced sublimation process, as a source, CdTe is placed in the crucible prior to deposition of CdTe film. With the formation of CdTe film on the glass sheet substrate, the filling level of CdTe in the crucible decreases, leading to the increase of distance between the glass sheet substrate and the source. As a result, the microstructure and the resulting electrical properties of CdTe film changes with time.

Conventional close-spaced sublimation processes load a starting material to an acceptable filling level in a crucible prior to deposition. To replenish the source consumed in the film deposition, it needs to be reloaded to the crucible. Since the heated vessel used in the method contains toxic vapors, which poses significant safety problem when it is opened for reloading during deposition, it is required to cool down prior to reloading the source. Thus, continuous production of CdTe film on the glass sheet substrate is interrupted to reload the source to the crucible. In practice, since only a small volume of CdTe is needed to form a thin CdTe film, a fully loaded crucible can be used for CdTe deposition for many days. However, with the deposition of CdTe film on the glass sheet substrate, the amount of CdTe source material in the crucible decreases with time, leading to the increase of the distance between the glass sheet substrate and the source and the change of morphology of CdTe polycrystalline. With the repetition of the CdTe film deposition, dispersions in thickness and in quality of the CdTe film increases gradually. Thereafter, it is not clear if the uniformity of deposition over time and across large substrates is achieved. Furthermore, the microstructure and morphology of CdTe particles left in the crucible change with deposition time, increasing the uncertainty of the film uniformity over time and large area substrate.

### SUMMARY OF THE INVENTION

In view of the above-described problems, it is one objective of the invention to provide a method for depositing a semiconductor film, in which semiconductor materials are fed to a vacuum deposition device continuously or periodically without opening a vacuum deposition chamber thereof.

It is another objective of the invention to provide a device for depositing a semiconductor film that supplies semiconductor materials continuously or periodically without opening a vacuum deposition chamber thereof.

To achieve the above objectives, in accordance with one embodiment of the invention, there is provided a method for depositing a semiconductor film using close-spaced sublimation technique, the method comprising the steps of:
a) carrying a semiconductor material by a carrier gas to a crucible installed in a vacuum deposition chamber via a passage; and
b) heating the crucible to sublimate the semiconductor material to be vapor and depositing the vapor on a substrate.

In a class of this embodiment, the method further comprises providing a feeding distributor to uniformly distribute the semiconductor material carried by the carrier gas in the crucible.

In a class of this embodiment, the feeding distributor is a perforated manifold.

In a class of this embodiment, the perforated manifold is made from stainless steel, graphite, or silicon carbide.

In a class of this embodiment, the carrier gas is nitrogen, argon, helium, or a mixture thereof.

In a class of this embodiment, in the step b), a heated permeable membrane is provided in the crucible; the sublimated semiconductor material, together with the carrier gas, passes through the heated permeable membrane and deposits on the substrate with a surface temperature lower than that of the sublimated semiconductor material; non-vaporized solid semiconductor material is further sublimated to be vapor in the heated permeable membrane, and solid semiconductor material is blocked by the permeable membrane and cannot deposit on the substrate.

In a class of this embodiment, the permeable membrane is heated to be 2-5° C. higher than the temperature of the crucible.

In accordance with another embodiment of the invention, there provided is a device for depositing a semiconductor film using close-spaced sublimation technique, comprising a semiconductor material feeding device, a passage, a vacuum deposition chamber, a crucible installed in the vacuum deposition chamber, and a substrate located above the crucible, wherein the semiconductor material feeding device and the crucible are connected via the passage, the semiconductor material feeding device supplies a semiconductor material and a carrier gas, and the semiconductor material is carried by the carrier gas and enters the crucible via the passage.

In a class of this embodiment, a feeding distributor is disposed in the crucible to uniformly distribute the semiconductor material.

In a class of this embodiment, the feeding distributor is a perforated manifold, and the perforated manifold is connected with the passage.

In a class of this embodiment, the crucible is equipped with a permeable membrane; the permeable membrane is heatable and allows vaporized semiconductor material and carrier gas to pass through; the substrate is located above the permeable membrane, and the semiconductor material is heated and sublimated in the crucible to be vapor; and the vapor passes through the permeable membrane and deposits on the substrate.

In a class of this embodiment, the semiconductor material feeding device comprises a carrier gas tank connected with the passage, a hopper connected with the passage, and a feeding control device which controls the feeding rate of the semiconductor material in the hopper.

Advantages of the invention are summarized below. The semiconductor material is carried into the crucible installed in the vacuum deposition chamber by the carrier gas via the passage, leading to the semiconductor material to enter continuously or periodically the vacuum deposition device without opening the vacuum deposition chamber thereof. Distributing the semiconductor material carried by the carrier gas in the crucible uniformly through the feeding distributor overcomes technical difficulties in the art in which the filling level of CdTe in the crucible decreases with the formation of CdTe film on the glass substrate, leading to the increase of distance between the glass sheet substrate and the source. As a result, the uniformity of thin film on the substrate can be controlled effectively in the invention. The introduction of the permeable membrane is to withhold the non-vaporized semiconductor material in the crucible and allow the carrier gas and vaporized semiconductor material to pass through and then deposit on the substrate to form a thin film. The permeable membrane is thermal conductive to avoid condensation of the vaporized semiconductor material in the permeable membrane. The condensation will jam the pores in the permeable membrane and block the flow of vapor. Moreover, the non-vaporized semiconductor powder can also be further vaporized to be vapor in the permeable membrane. The feeding rate of semiconductor material is controlled to meet the requirement of thin film deposition exactly.

### BRIEF DESCRIPTION OF THE DRAWINGS

FIG. 1 is a sectional view of a device for depositing a semiconductor film according to one embodiment of the invention;

FIG. 2 is a planar view of a perforated manifold in a crucible according to one embodiment of the invention;

FIG. 3 is a sectional view of a vapor deposition device according to one embodiment of the invention;

FIG. 4 is a sectional view of a vapor deposition device according to another embodiment of the invention;

FIG. 5 is a longitudinal sectional view illustrating a deposition process on a substrate in which a semiconductor material is conveyed by a metal conveyer according to one embodiment of the invention; and

FIG. 6 is a schematic diagram of a semiconductor material feeding device according to one embodiment of the invention.

### DETAILED DESCRIPTION OF THE EMBODIMENTS

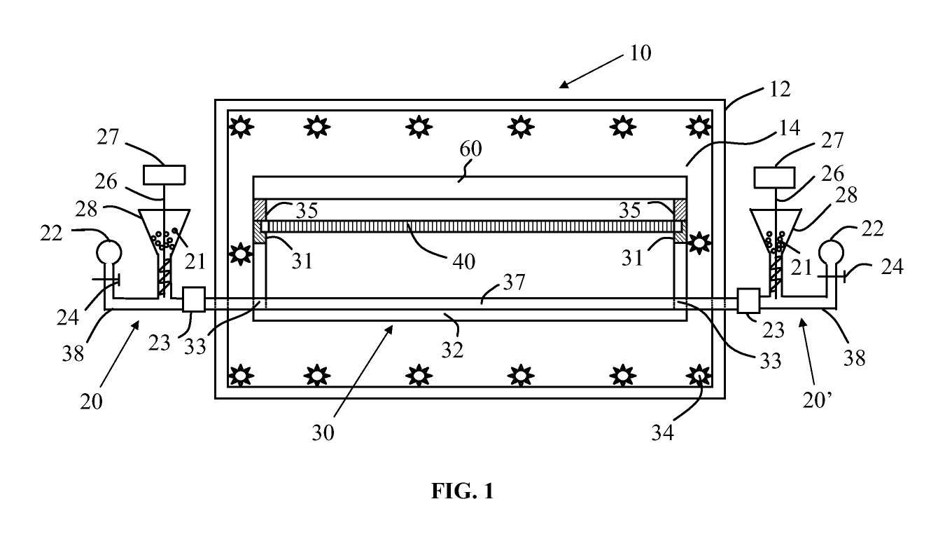

As shown in FIG. 1, a device for depositing a semiconductor film 10 comprises a semiconductor material feeding device 20 and a vacuum deposition chamber 14. The structure of the semiconductor material feeding device 20 and the vacuum deposition chamber 14 will be fully described thereafter. Two different practices of depositing a semiconductor material on a glass sheet substrate 60 to form a semiconductor layer are performed. One is to deposit the semiconductor material on the substrate 60 that is placed on the top of the crucible 32 until the thickness of the semiconductor layer meets requirement, while the other practice is to deposit the semiconductor material on a moving substrate that is conveyed by a metal conveyer 36. The substrate is moved forward with the metal conveyer 36.

The device for depositing a semiconductor film 10 is used to deposit a semiconductor material to form a thin film on the glass sheet substrate 60, for example, a CdS and CdTe thin film in CdS/CdTe solar cells. However, it should be noted that other substrates and deposition materials can also be utilized in accordance with the invention. For example, other materials comprise those that can be sublimated to be vapor at moderate temperatures and other substrates comprise metal substrates such as foils.

The device for depositing a semiconductor film 10 comprises an insulated housing 12 defining the vacuum deposition chamber 14. The semiconductor material is deposited on the glass sheet substrate 60 in the vacuum deposition chamber 14. The housing 12 is heated in any suitable manner, for example, by a halogen lamp 34, to keep the temperature therein at between 400 and 650° C. The vacuum deposition chamber comprises a vapor deposition device 30. The vapor deposition device 30 comprises a crucible 32 where the semiconductor material is heated and sublimated to be vapor. The crucible 32 comprises a feeding distributor used to distribute the semiconductor material uniformly. The feeding distributor can be a perforated manifold 37 or any distributor capable of distributing the semiconductor material uniformly. The distributor employed in the embodiment is the perforated manifold 37. The vapor deposition device 30 further comprises a heatable permeable membrane 40 fixed on the crucible 32. The substrate 60 is placed above the permeable membrane 40. The permeable membrane 40 and substrate 60 are separated with a spacer 35 made of insulating materials.

In the embodiment of FIG. 1, the spacer 35, made of insulating material ceramic, separates the permeable membrane 40 from the substrate 60, ensuring that the temperature of the permeable membrane is higher than that of the substrate. The distance between the permeable membrane 40 and the substrate glass is between 2 and 30 mm, preferably, 10 mm. The perforated manifold 37 is made of stainless steel, graphite, or silicon carbide. The semiconductor material is heated in the heated crucible and sublimated to be vapor and deposits on the glass sheet substrate 60 after passing through the permeable membrane. The semiconductor material in the crucible is heated during the vapor deposition to a slightly higher in temperature than the glass substrate, which is about 500 to 750° C.

The semiconductor material feeding device 20 is connected with the crucible 32 via a passage 38. The passage 38 connects with the perforated manifold 37. The semiconductor material feeding device 20 supplies the semiconductor material and carrier gas. The semiconductor material, carried by the carrier gas and passing through the passage 38 and perforated manifold 37, is uniformly distributed in the crucible. The crucible 32 is heated to vaporize the semiconductor material to be vapor. The semiconductor vapor, together with the carrier gas, passes through the heated permeable membrane and then deposits on the substrate. The surface temperature of the substrate is slightly lower than that of the semiconductor vapor. Non-vaporized semiconductor material inside the heated permeable membrane is further sublimates to be vapor, while the solid semiconductor material is blocked by the permeable membrane and cannot deposit on the glass sheet substrate.

The carrier gas is nitrogen, argon, helium, or a mixture thereof. The preferred semiconductor material is powder. Two different practices of introducing the semiconductor material into the crucible 32 in the vacuum deposition chamber have been performed. In one such practice, the semiconductor material is continuously introduced into the crucible 32 by the carrier gas without opening the vacuum deposition chamber and without interrupting the continuous deposition process, the feeding rate of the semiconductor material meets the deposition requirement exactly. Another such practice of introducing the semiconductor material into the crucible 32 by the carrier gas is performed periodically without opening the vacuum deposition chamber.

The permeable membrane 40 is supported with an L-shaped holder 31 and fixed at the top of the crucible 32. The L-shaped holder 31 is preferably made of an insulating ceramic material, for example, alumina ceramic. A preferred structure for the permeable membrane is that only the carrier gas and semiconductor vapor are allowed to pass through, while all non-vaporized semiconductor material is blocked inside the crucible. A heater can be disposed inside the permeable membrane 40 to adjust the temperature thereof. The permeable membrane 40 itself can functions as a heater and thus a voltage is applied at both ends thereof to adjust the temperature. The permeable membrane 40 is heated to be 2-5° C. higher than the temperature of the crucible. As a result, the semiconductor vapor cannot condense at the surface of the permeable membrane and inside the pores. Otherwise, the passage of the semiconductor vapor in the permeable membrane is jammed by the condensation of the vapor, leading to the blockage of vapor flowing in the pores. The preferable material for the crucible 32 is graphite.

The permeable membrane 40 is selected from the group consisting of graphite, silicon carbide, silicon nitride, and boron nitride. The preferable material of the permeable membrane 40 is heatable graphite. The permeable material made of heatable graphite has good thermal conductivity. The pores in the permeable membrane 40 are distributed regularly. The preferred size of the pores in the membrane is in micro-range and its porosity is above 25% such that only the carrier gas and the semiconductor vapor can pass through. The non-sublimated semiconductor material is blocked in the crucible until it is sublimated to be vapor in the permeable membrane 40. The thickness of the permeable membrane 40 is 1-10 mm. In the present embodiment, the permeable membrane is 2 mm in thickness.

As shown in FIG. 1, the semiconductor material feeding device 20 comprises a carrier gas cylinder 22 connected with the passage 38, a hopper 28 connected the passage 38, and a feeding control device controlling the feeding rate of the semiconductor material in the hopper.

The carrier gas cylinder 22 generates the carrier gas. The semiconductor material feeding device 20 further comprises a rotary screw 26 equipped with an actuator 27, a vibrating feeder, or a combination thereof. The feeding rate of the semiconductor material is precisely controlled by the rotating speed of the rotary screw 26 in the hopper 28. Another method of controlling the feeding rate is achieved by varying vibrating frequency of the vibrating feeder.

In the embodiment, the feeding controlling device comprises the rotary screw 26 and the actuator 27 which drives the rotary screw 26 to rotate at a certain speed. The rotary screw 26 is controlled by the actuator 27, introducing the semiconductor powder 21 into the passage 38 at a certain rotating speed and further into the perforated manifold 37 in the vapor deposition device 30. The flow rate of the carrier gas is controlled by an adjustable valve 24 to maintain the carrier gas at a certain flow rate, ensuring that the semiconductor material 21 flows into the crucible 32 at an expected rate. A preferred feeding approach is: the feeding rate of the semiconductor material carried by the carrier gas to the crucible 32 is controlled to meet the requirement of semiconductor deposition, so that no accumulation or scarcity of the semiconductor material occurs in the crucible 32. As shown in FIG. 1, the material feeding device 20 further comprises an observation window 23 disposed on the passage 38, which is used to observe the flow of the semiconductor material.

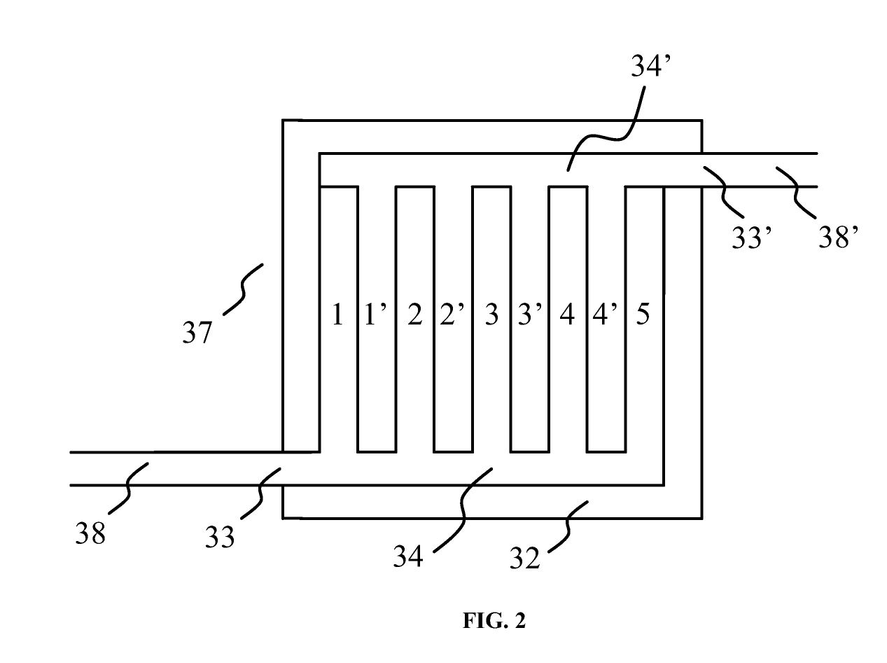

As shown in FIG. 2, the perforated manifold 37 comprises a plurality of parallel channels 1, 1′, 2, 2′, 3, 3′, 4, 4′, and 5 and two entry passages 34 and 34′ at both ends thereof. The preferred width of these parallel channels is 5-10 mm. The entry passage 34 is connected with the channels 1, 2, and 3, and the entry passage 34′ with the channels 1′, 2′, and 3′. The entry passage 34 has an entry 33, and the entry passage 34′ has an entry 33′. Through the entry 33 and 33′ and the passage 38 and 38′ at both ends of the vapor deposition device 30, the perforated manifold 37 in the crucible 32 is connected with the semiconductor material feeding device 20.

The carrier gas from the carrier gas cylinder carries the semiconductor material powder to the perforated manifold 37 via the entry 33. As a result, the semiconductor material powder is distributed uniformly in the crucible 32. Another semiconductor material feeding device 20′ introduces the carrier gas and semiconductor material powder into the crucible 32 via the entry 33′ in the same manner as above. As such, there is a good distribution of the carrier gas and entrained semiconductor powder along the entire space of the crucible 32, ensuring that the vapor in the space between the permeable membrane 40 and the glass sheet substrate 60 is distributed uniformly on the whole surface of the glass sheet substrate 60, and ensuring that the semiconductor film deposited on the surface of the glass sheet substrate 60 is uniform.

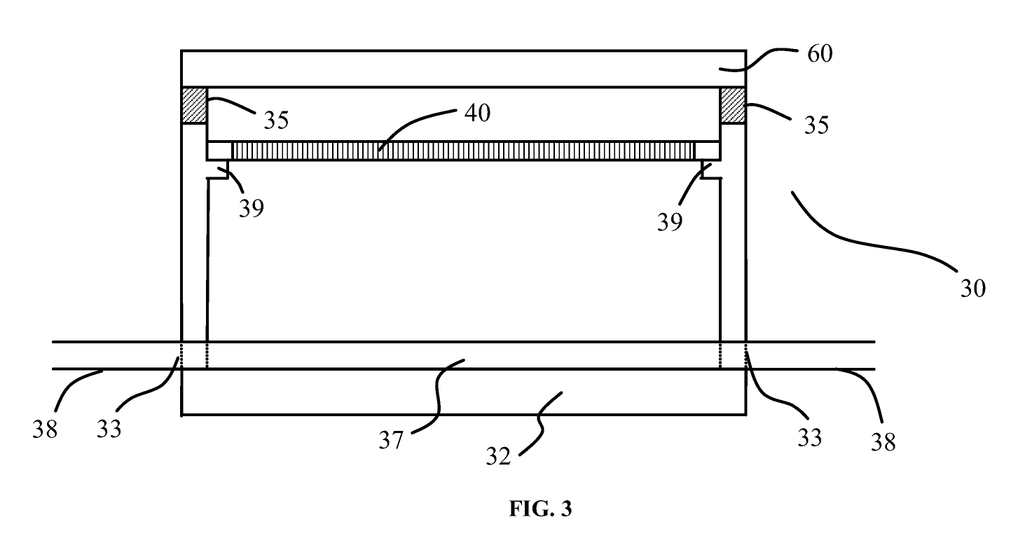

FIGS. 1, 3, and 4, respectively, discloses different embodiments of the vapor deposition devices 30, 30′, and 30″. More specifically, the vapor deposition device 30 as shown in FIG. 1 has an L-shaped block 31 made of ceramic to hold the permeable membrane 40 on the top of the crucible 32. The vapor deposition device 30′ as shown in FIG. 3 has a pair of pins 39 made of graphite inside the crucible 32 to support the permeable membrane 40. Both the vapor deposition devices 30 and 30′ are suitable for the deposition of the semiconductor material on the glass sheet substrate periodically or continuously. In these two vapor deposition devices, the size of the crucible must match the size of the substrate.

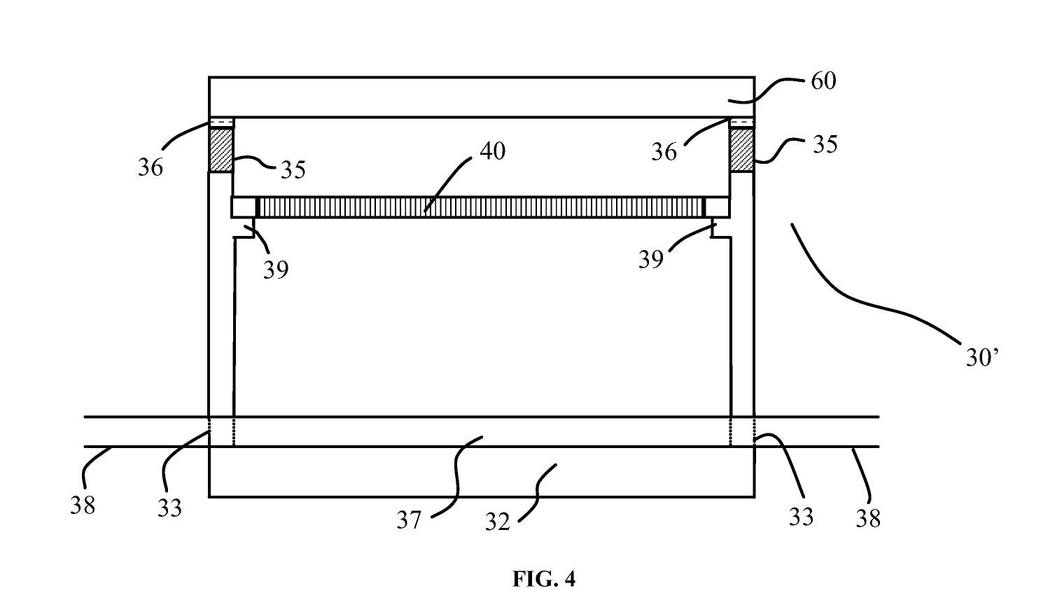

The vapor deposition device 30″ as shown in FIG. 4 comprises the metal conveyer 36 used to convey and support the glass sheet substrate 60 for continuous production of a thin film on the glass sheet substrate. The glass sheet substrate 60 is directly placed on the metal conveyer 36. The metal conveyer 36 and the crucible 32 are separated with the spacer 35. The spacer 35 is made of a ceramic material with low friction coefficient. There is no gap between the metal conveyer 36 and the crucible 32 and thus no semiconductor vapor leakage occurs on both sides of the crucible 32. The carrier gas, passing through the permeable membrane 40, discharges along the other two sides of the crucible 32. The loss of the semiconductor vapor is minimized by reducing the gap between the glass sheet substrate 60 and the spacer 35 and opening space between two adjacent glass sheet substrates 60. The preferred gap between the glass sheet substrate 60 and the spacer 35 is between 0.2-0.5 mm. With the help of metal conveyer 36, the glass sheet substrate can be moved in and out of the vacuum deposition chamber 14. The size of the crucible in the vapor deposition device 30″ may be equal to or smaller than that of the glass sheet substrate. The metal conveyer 36 can also be located on the spacer 35 as shown in FIG. 1.

A preferred operation mode of feeding the semiconductor material and a preferred vacuum deposition device are described below. When the crucible is equal to the glass sheet substrate in size, the semiconductor material powder is introduced to the perforated manifold 37 in the heated vapor deposition device 30 and then flows into the crucible 32 where the semiconductor material is sublimated to be vapor. The vaporized semiconductor passes through the heated permeable membrane 40 located on the top of the crucible 32 and then deposits to form a semiconductor film on the glass sheet substrate that is placed on the vapor deposition device 30 and conveyed by a pair of the metal conveyer 36. After the deposition is over, the semiconductor material-coated substrate 60 on the metal conveyer 36 is moved away from the vapor deposition device 30 by the metal conveyer 36. After that, another glass sheet substrate on the metal conveyer 36 is moved to the top of the crucible 32 rapidly where the semiconductor vapor passes through the permeable membrane 40 and then deposits on the surface of the glass sheet substrate 60.

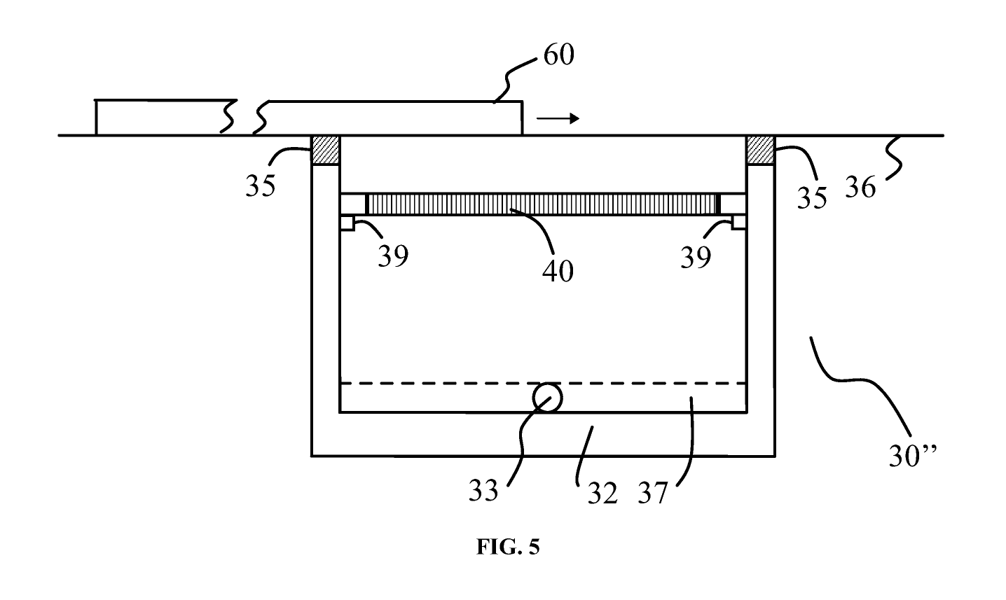

During this deposition process, the loss of the semiconductor material depends on the movement speed of the metal conveyer 36 and the open distance between two adjacent substrates. Another operation mode of deposition of the semiconductor film is as shown in FIG. 4, in which the glass sheet substrate 60 are different from the crucible 32 in size, e.g., the width of the crucible 32 is less than the length of the glass sheet substrate 60 along the conveying direction of the metal conveyer 36, as illustrated in FIG. 5. In this embodiment of operation, the metal conveyer 36 conveys the glass sheet substrate 60 at a certain speed along the direction of arrow as illustrated in FIG. 5. In the meantime, the semiconductor vapor, which is formed by sublimating in the crucible 32 and carried by the carrier gas, passes through the permeable membrane 40 and then deposits on the surface of the glass sheet substrate to form a semiconductor film. In the same manner, the semiconductor material consumed during the deposition is complemented to the crucible 32 by the carrier gas at a certain rate from the hopper 28 located outside the vacuum deposition chamber. The opening distance between two adjacent glass substrates can be adjusted as required in practice. To reduce the loss of the semiconductor vapor, the opening distance between two adjacent substrates in the vacuum deposition chamber is controlled to be less than 1 cm.

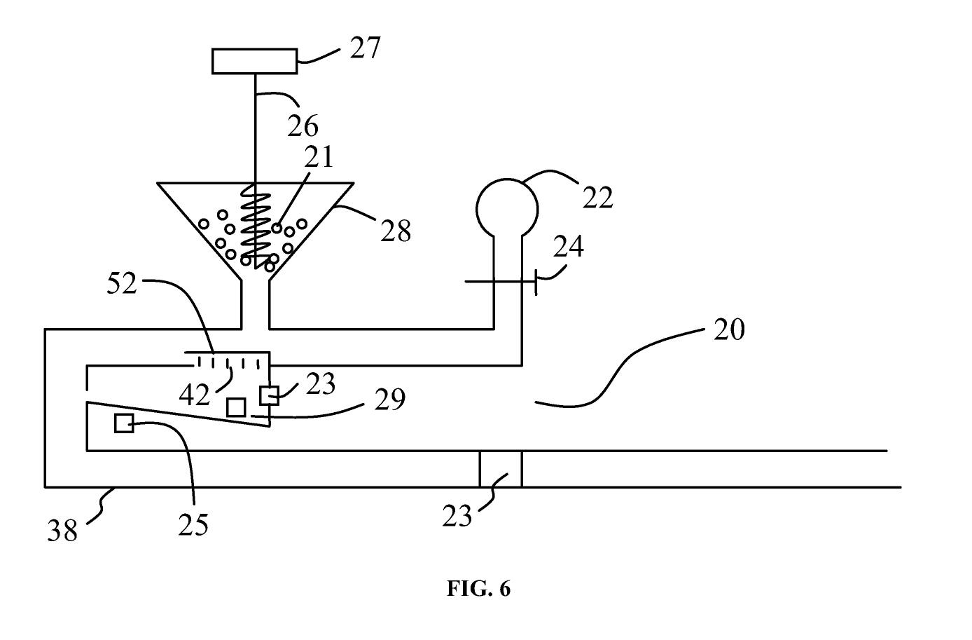

As shown in FIG. 6, another embodiment of the semiconductor material feeding device 20 for deposition of semiconductor material on the glass sheet substrate, i.e., the semiconductor material powder 21, passing through the passage 38 from the hopper 28 by rotating the rotary screw 26, enters the vapor deposition device 30. The feeding control device comprises a container 29 equipped with a vibratory feeder and a shutter 52. The passage 38 is provided with a plurality of holes 42 receiving the semiconductor material to flow into the container 29. The shutter 52 blocks all or some of the holes 42. The container 29 is connected with the hopper 28 via another passage which is not shown in FIG. 6.

When the amount of the semiconductor material required by the device for depositing a semiconductor film 10 cannot be achieved by varying the rotating speed of the rotary screw 26, the feeding rate of the semiconductor material can be controlled as follows. The shutter 52 blocks part of the holes underneath, and some of the semiconductor material from the hopper 28 enters the container 29 by passing through the holes 42 which are not blocked by the shutter 52 and the rest is carried to the perforated manifold 37 by the carrier gas. When the semiconductor material 21 has been accumulated to a certain of amount in the container 29, it can be fed back to the hopper 28 using a specific passage (not shown in FIG. 6) or ramped up to the passage 38 by a vibratory machine 25. Thus, the feeding rate of the semiconductor material to the vapor deposition device 30 is controlled precisely. The amount of the semiconductor material accumulated in the container 29 is monitored with the observation window 23.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method for depositing a semiconductor film, comprising:
a) carrying a semiconductor material by a carrier gas to a crucible installed in a vacuum deposition chamber via a passage; and
b) heating the crucible to sublimate the semiconductor material to be vapor and depositing the vapor on a substrate.

2. The method of claim 1 further comprising providing a feeding distributor to uniformly distribute the semiconductor material carried by the carrier gas in the crucible.

3. The method of claim 2, wherein the feeding distributor is a perforated manifold made from stainless steel, graphite, or silicon carbide.

4. The method of claim 1, wherein the carrier gas is nitrogen, argon, helium, or a mixture thereof.

5. The method of claim 1, wherein
in the step b), a heatable permeable membrane is provided in the crucible;
the sublimated semiconductor material, together with the carrier gas, passes through the heated permeable membrane and deposits on the substrate with a surface temperature lower than that of the sublimated semiconductor material;
non-vaporized solid semiconductor material is further sublimated to be vapor in the heated permeable membrane; and
solid semiconductor material is blocked by the permeable membrane and cannot deposit on the substrate.

6. The method of claim 2, wherein
in the step b), a heatable permeable membrane is provided in the crucible;
the sublimated semiconductor material, together with the carrier gas, passes through the heated permeable membrane and deposits on the substrate with a surface temperature lower than that of the sublimated semiconductor material;
non-vaporized solid semiconductor material is further sublimated to be vapor in the heated permeable membrane; and
solid semiconductor material is blocked by the permeable membrane and cannot deposit on the substrate.

7. The method of claim 5, wherein the thickness of the permeable membrane is between 1 and 10 mm.

8. The method of claim 5, wherein the permeable membrane is made from a material selected from the group consisting of graphite, silicon carbide, silicon nitride, and boron nitride.

9. The method of claim 5, wherein the permeable membrane is heated to be 2-5° C. higher than the crucible in temperature.

10. The method of claim 9, wherein the permeable membrane is heated using a voltage disposed at both ends thereof or a heater embedded therein.

11. A device for depositing a semiconductor film, comprising:
a) a semiconductor material feeding device (20);
b) a passage (38);
c) a vacuum deposition chamber (14);
d) a crucible (32) installed in the vacuum deposition chamber; and
e) a substrate (60) located above the crucible;
wherein
the semiconductor material feeding device (20) and the crucible (32) are connected via the passage (38);
the semiconductor material feeding device (20) supplies a semiconductor material and a carrier gas; and
the semiconductor material is carried by the carrier gas and enters the crucible (32) via the passage (38).

12. The device of claim 11, wherein a feeding distributor is disposed in the crucible (32) to uniformly distribute the semiconductor material.

13. The device of claim 12, wherein the feeding distributor is a perforated manifold (37), and the perforated manifold (37) is connected with the passage (38).

14. The device of claim 11, wherein
the crucible (32) is equipped with a permeable membrane (40);
the permeable membrane (40) is heatable and allows vaporized semiconductor material and carrier gas to pass through;
the substrate (60) is located above the permeable membrane (40);
the semiconductor material is heated and sublimated in the crucible (32) to be vapor; and
the vapor passes through the permeable membrane (40) and deposits on the substrate (60).

15. The device of claim 12, wherein
the crucible (32) is equipped with a permeable membrane (40);
the permeable membrane (40) is heatable and allows vaporized semiconductor material and carrier gas to pass through;
the substrate (60) is located above the permeable membrane (40);
the semiconductor material is heated and sublimated in the crucible (32) to be vapor; and
the vapor passes through the permeable membrane (40) and deposits on the substrate (60).

16. The device of claim 14, wherein the permeable membrane (40) is embedded with a heater.

17. The device of claim 15, wherein the permeable membrane (40) is embedded with a heater.

18. The device of claim 14, wherein the permeable membrane (40) itself is a heating element.

19. The device of claim 15, wherein the permeable membrane (40) itself is a heating element.

20. The device of claim 14, wherein the permeable membrane (40) is supported with an L-shaped holder (31) made from an insulating material and installed on the crucible (32).

21. The device of claim 14, wherein the distance between the permeable membrane (40) and the substrate (60) is between 2 and 30 mm.

22. The device of claim 11, wherein the semiconductor material feeding device (20) comprises a carrier gas tank (22) connected with the passage (38), a hopper (28) connected with the passage (38), and a feeding control device which controls the feeding rate of the semiconductor material in the hopper (28).

23. The device of claim 12, wherein the semiconductor material feeding device (20) comprises a carrier gas tank (22) connected with the passage (38), a hopper (28) connected with the passage (38), and a feeding control device which controls the feeding rate of the semiconductor material in the hopper (28).

24. The device of claim 22, wherein the semiconductor material feeding device (20) further comprises a rotary screw (26) disposed in the hopper (28) and an actuator (27) driving the rotary screw (26) to rotate.

25. The device of claim 22, wherein
the feeding control device comprises a container (29) equipped with a vibratory feeder and a shutter (52);
the passage (38) is provided with a plurality of holes (42) receiving the semiconductor material to flow into the container (29);
the shutter (52) blocks all or some of the holes (42); and
the container (29) is connected with the hopper (28) via another passage.

26. The device of claim 11, wherein the substrate (60) is located on a conveyer (36).

27. The device of claim 12, wherein the substrate (60) is located on a conveyer (36).
